(19) United States
(12) Patent Application Publication
(10) Pub. No.: US 2023/0202916 A1
(43) Pub. Date: Jun. 29, 2023

(54) GLASS SUBSTRATE, FABRICATING METHOD OF THE SAME, AND DISPLAY DEVICE HAVING THE SAME

(71) Applicant: SAMSUNG DISPLAY CO., LTD., Yongin-si (KR)

(72) Inventors: Hoi Kwan Lee, Yongin-si (KR); Myung Hwan Kim, Yongin-si (KR); Seung Kim, Yongin-si (KR); Seung Ho Kim, Yongin-si (KR); Eun Kyung Yeon, Yongin-si (KR); Jeong Seok Lee, Yongin-si (KR); Ik Hyung Park, Yongin-si (KR); Jong Hoon Yeum, Yongin-si (KR)

(21) Appl. No.: 18/176,466

(22) Filed: Feb. 28, 2023

Related U.S. Application Data
(62) Division of application No. 14/991,824, filed on Jan. 8, 2016.

(30) Foreign Application Priority Data
May 4, 2015 (KR) 10-2015-0062691

(51) Int. Cl. C03C 21/00; H10K 77/10

(52) U.S. Cl. CPC C03C 21/002; C03C 21/008; H10K 77/111; Y02E 10/549; H10K 2102/311

(57) ABSTRACT

A glass substrate has a first surface, a second surface opposite to the first surface, and a thickness from the first surface to the second surface. The glass substrate includes a first region, a second region, and a third region. The first region extends from the first surface a first depth into the glass substrate and has a first compressive stress. The second region extends from the second surface a second depth into the glass substrate and has a second compressive stress different from the first compressive stress. The third region is between the first region and the second region. In the glass substrate, the first compressive stress has a maximum value at a location between the first surface and the first depth, and the second compressive stress has a maximum value at a location between the second surface and the second depth.

### CROSS-REFERENCE TO RELATED APPLICATIONS

This application is a divisional of U.S. patent application Ser. No. 14/991,824, filed Jan. 8, 2016, which claims priority to and the benefit of Korean Patent Application No. 10-2015-0062691, filed May 4, 2015, the entire content of both of which is incorporated herein by reference.

### BACKGROUND

### 1. Field

Embodiments of the present invention relate to a glass substrate, a fabricating method of the same, and a display device having the same.

### 2. Description of the Related Art

Flexible display devices that use flat panel displays have recently been developed. Flat panel displays include liquid crystal displays (LCDs), organic light-emitting diode (OLED) displays, electrophoretic displays (EPDs), and the like.

Flexible display devices can have curving and folding characteristics, and hence can be folded or rolled. Accordingly, the flexible display devices are easy to carry and can have large screens. The flexible display devices can be applied to various suitable fields, for example, mobile equipment such as a mobile phone, a portable multimedia player (PMP), a navigation system, an ultra-mobile PC (UMPC), an electronic book, and an electronic paper, as well as TVs, monitors, and the like.

### SUMMARY

Embodiments of the present invention provide a glass substrate having resistance to damage caused when the glass substrate is bent or rolled.

Some embodiments provide a method of fabricating the glass substrate.

Some embodiments provide a display device employing the glass substrate.

According to an embodiment of the present invention, there is provided a glass substrate having a first surface, a second surface opposite to the first surface, and a thickness from the first surface to the second surface, the glass substrate including: a first region extending from the first surface a first depth into the glass substrate, the first region having a first compressive stress; a second region extending from the second surface a second depth into the glass substrate, the second region having a second compressive stress different from the first compressive stress; and a third region between the first region and the second region, wherein the first compressive stress has a maximum value at a location between the first surface and the first depth, and wherein the second compressive stress has a maximum value at a location between the second surface and the second depth.

The third region may have a tensile stress.

The maximum value of the first compressive stress may be smaller than that of the second compressive stress.

The first depth may be smaller than the second depth.

The first region and the second region may have a first ion, and the third region may have a second ion different from the first ion.

The first ion may be a K⁺ ion and the second ion may be a Na⁺ or Li⁺ ion.

According to another embodiment of the present invention, there is provided a method of fabricating a glass substrate, the method including: preparing a mother glass substrate having a first surface and a second surface opposite to the first surface; concavely curving at least one portion of the first surface of the mother glass substrate; immersing the mother glass substrate in a first ion exchange salt solution including a first ion in the state in which the mother glass substrate is curved; and primarily heating the mother glass substrate.

The method may further include immersing the mother glass substrate in a second ion exchange salt solution including a second ion different from the first ion

The method may further include secondarily heating the mother glass substrate after the mother glass substrate is immersed in the second ion exchange salt solution.

The secondary heating may be performed at a lower temperature and for a shorter time that the primary heating.

The first ion may be a K⁺ ion and the second ion may be a Na⁺ ion.

According to an embodiment of the present invention, there is provided a method of fabricating a glass substrate, the method including: preparing a mother glass substrate having a first surface and a second surface opposite to the first surface; coating a first dry paste including a first ion on the first surface; coating a second dry paste including the first ion and a second ion on the second surface; and heating the mother glass substrate on which the first and second dry pastes are coated.

The first ion may be a K⁺ ion and the second ion may be a Na⁺ ion.

According to another embodiment of the present invention, there is provided a method of fabricating a glass substrate, the method including: preparing a mother glass substrate having a first surface and a second surface opposite to the first surface; immersing the mother glass substrate in an ion exchange salt solution; heating the mother glass substrate; and slimming the first surface of the mother glass substrate.

According to another embodiment of the present invention, there is provided a display device including a glass substrate having a first surface, a second surface opposite to the first surface, and a thickness from the first surface to the second surface; and pixels on the glass substrate, wherein the glass substrate includes: a first region extending from the first surface a first depth into the glass substrate, the first region having a first compressive stress; a second region extending from the second surface a second depth into the glass substrate, the second region having a second compressive stress different from the first compressive stress; and a third region between the first region and the second region, wherein the first compressive stress has a maximum value at a location between the first surface and the first depth in the first region, and wherein the second compressive stress has a maximum value at a location between the second surface and the second depth in the second region.

The glass substrate may be in either a flat mode or a folded mode based on whether the glass substrate is folded. The glass substrate may be configured to be folded in a direction in which a portion of the first surface faces another portion of the first surface when in the folded mode.

The glass substrate may be in either a flat mode or a rolled mode based on whether the glass substrate is rolled. The glass substrate may be configured to be rolled such that a portion of the second surface faces the first surface when in the rolled mode.

In the glass substrate, and in the display having the same, according to embodiments of the present invention, the display device is prevented or substantially prevented from being damaged due to a brittle fracture caused when the display device is curved or rolled in a manner causing a tensile stress to be applied.

### BRIEF DESCRIPTION OF THE DRAWINGS

Example embodiments will now be described more fully hereinafter with reference to the accompanying drawings; however, the present invention may be embodied in different forms and should not be construed as limited to the embodiments set forth herein. Rather, these embodiments are provided so that this disclosure will be thorough and complete, and will fully convey the scope of the example embodiments to those skilled in the art.

FIG. 1 is a sectional view illustrating a glass substrate according to an embodiment of the present invention.

FIG. 2 is a graph illustrating stresses with respect to distances from a surface of the glass substrate of FIG. 1.

FIG. 3A is a sectional view illustrating an existing glass substrate together with a graph illustrating stresses with respect to distances from a surface of the glass substrate.

FIG. 3B is a sectional view illustrating the glass substrate according to the present embodiment together with a graph illustrating stresses with respect to distances from a surface of the glass substrate.

FIG. 4 is a flowchart illustrating a method of fabricating the glass substrate according to an embodiment of the present invention.

FIG. 5 is a flowchart illustrating another method of fabricating the glass substrate according to an embodiment of the present invention.

FIG. 6 is a sectional view illustrating a glass substrate according to another embodiment of the present invention.

FIG. 7 is a flowchart illustrating a method of fabricating the glass substrate shown in FIG. 6.

FIG. 8 is a graph illustrating stresses with respect to distances from a surface of the glass substrate corresponding to FIG. 1 according to still another embodiment of the present invention.

FIG. 9 is a flowchart illustrating a method of fabricating a glass substrate having the characteristic shown in the graph of FIG. 8.

FIG. 10 is a perspective view illustrating a display device according to an embodiment of the present invention.

FIG. 11A is a sectional view illustrating when the display device of FIG. 10 is folded.

FIG. 11B is a sectional view illustrating when the display device of FIG. 10 is rolled.

FIG. 12 is a perspective view illustrating a display device according to another embodiment of the present invention.

FIG. 13A is a sectional view illustrating when the display device of FIG. 12 is folded.

FIG. 13B is a sectional view illustrating when the display device of FIG. 12 is rolled.

### DETAILED DESCRIPTION

Embodiments of the present invention will be described more fully hereinafter with reference to the accompanying drawings, in which exemplary embodiments of the present invention are shown. The present invention may, however, be embodied in many different forms and should not be construed as limited to the embodiments set forth herein; rather, these embodiments are provided so that this disclosure will be thorough and complete, and will fully convey the scope of the present invention to those skilled in the art.

Like numbers refer to like elements (or components) throughout. In the drawings, the thickness of certain lines, layers, components, elements or features may be exaggerated for clarity.

It will be understood that, although the terms “first”, “second”, “third”, etc., may be used herein to describe various elements, components, regions, layers, and/or sections, these elements, components, regions, layers and/or sections should not be limited by these terms. These terms are used to distinguish one element, component, region, layer or section from another element, component, region, layer or section. Thus, a first element, component, region, layer, or section discussed below could be termed a second element, component, region, layer, or section, without departing from the spirit and scope of the present invention.

The terminology used herein is for the purpose of describing particular embodiments and is not intended to be limiting of the present invention. As used herein, the singular forms “a” and “an” are intended to include the plural forms as well, unless the context clearly indicates otherwise. It will be further understood that the terms “comprise,” “comprises,” “comprising,” “includes,” “including,” and “include,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on,” “connected to,” “coupled to,” “connected with,” “coupled with,” or “adjacent to” another element or layer, it can be “directly on,” “directly connected to,” “directly coupled to,” “directly connected with,” “directly coupled with,” or “directly adjacent to” the other element or layer, or one or more intervening elements or layers may be present. Further “connection,” “connected,” etc. may also refer to “electrical connection,” “electrically connect,” etc. depending on the context in which they are used as those skilled in the art would appreciate. When an element or layer is referred to as being “directly on,” “directly connected to,” “directly coupled to,” “directly connected with,” “directly coupled with,” or “immediately adjacent to” another element or layer, there are no intervening elements or layers present.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it will also be understood that when one element, component, region, layer and/or section is referred to as being “between” two elements, components, regions, layers, and/or sections, it can be the only element, component, region, layer and/or section between the two elements, components, regions, layers, and/or sections, or one or more intervening elements, components, regions, layers, and/or sections may also be present.

As used herein, the term “and/or” includes any and all combinations of one or more of the associated listed items. Expressions such as “at least one of,” when preceding a list of elements, modify the entire list of elements and do not modify the individual elements of the list. Further, the use of “may” when describing embodiments of the present invention refers to “one or more embodiments of the present invention.” Also, the term “exemplary” is intended to refer to an example or illustration.

As used herein, the term “substantially,” “about,” and similar terms are used as terms of approximation and not as terms of degree, and are intended to account for the inherent deviations in measured or calculated values that would be recognized by those of ordinary skill in the art.

As used herein, the terms “use,” “using,” and “used” may be considered synonymous with the terms “utilize,” “utilizing,” and “utilized,” respectively.

Hereinafter, exemplary embodiments of the present invention will be described in detail with reference to the accompanying drawings.

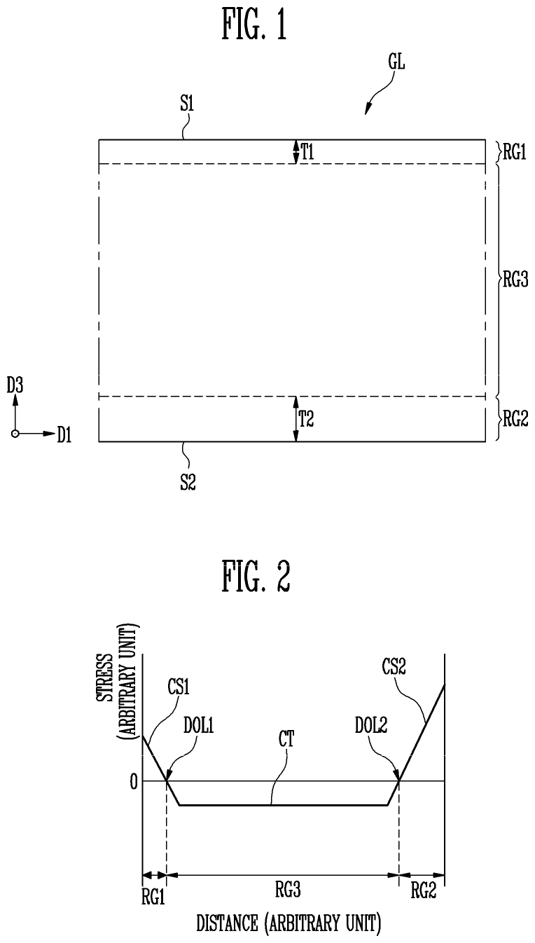

FIG. 1 is a sectional view illustrating a glass substrate GL according to an embodiment of the present invention, and FIG. 2 is a graph illustrating stresses with respect to distances from a surface of the glass substrate GL of FIG. 1.

Referring to FIGS. 1 and 2, the glass substrate GL has a plate shape having a first surface S1, and having a second surface S2 that is opposite to the first surface S1. The distance between the first surface S1 and the second surface S2 is defined as the thickness of the glass substrate GL.

In the present embodiment, it is assumed, for convenience of illustration, that the shape of the glass substrate GL on a plane is a rectangular shape having a pair of long sides and a pair of short sides. In addition, the direction of extension of the long side is designated as a first direction D1, the direction of extension of the short side is designated as a second direction D2, and the direction perpendicular to the directions of extension of the long side and of the short side is designated as a third direction D3.

The glass substrate GL according to the present embodiment is a glass that is chemically reinforced by an ion exchange process. In the present embodiment, the term “ion exchange process” means that a cation of the same valence in a glass is exchanged with a cation located on a surface of the glass, or in the vicinity of the glass, at a temperature that is equal to, or less than, a deformation point (e.g. a glass transition temperature) of the glass substrate GL. In other words, the term “ion exchange process” means that a cation (e.g., an alkaline metal cation, such as Na⁺ or Li⁺) in the glass is exchanged with another cation (e.g., a cation such as K⁺) from outside of the glass. The ion exchange process may provide a compressive stress profile extending a given depth into the glass substrate GL from a first surface and/or from a second surface of the glass. When a compressive stress is applied to the glass substrate, high strength is provided in curving of the glass substrate as long as a flaw exists in a region defined by a reference line, wherein the compressive stress is 0, and as defined by a compressive stress graph.

The glass substrate GL may include alkaline aluminosilicate and/or alkaline aluminoborosilicate, although the present invention is not limited thereto. In addition to the above-described material, the glass substrate GL may further include an alkaline earth oxide, etc.

Referring to FIG. 2, the glass substrate GL includes a first region RG1 extending a first depth DOL1 into the glass substrate GL from the first surface S1, a second region RG2 extending a second depth DOL2 into the glass substrate GL from the second surface S2, and a third region RG3 located between the first region RG1 and the second region RG2.

In the first region RG1, the first depth DOL1 is a depth where a cation in the glass substrate GL is exchanged with an external cation. Accordingly, the first region RG1 has a first thickness T1 (see FIG. 1). A first compressive stress CS1 is applied to the first region RG1 by the ion exchange. The first compressive stress CS1 decreases, based on a function (e.g., a predetermined function), from the first surface S1 to the first depth DOL1. The first compressive stress CS1 becomes 0 within the first depth DOL1. The total compressive stress stored in the first region RG1 may be represented by an area under the abovementioned function (e.g., an integral of the function) in the depth direction away from the first surface S1.

In the second region RG2, the second depth DOL2 is a depth at which a cation in the glass substrate GL is exchanged with an external cation. Accordingly, the second region RG2 has a second thickness T2 (see FIG. 1). A second compressive stress CS2 is applied to the second region RG2 by the ion exchange. The second compressive stress CS2 decreases, based on a function (e.g., a predetermined function), away from the second surface S2 toward the second depth DOL2. The second compressive stress CS2 becomes 0 at a point within the second depth DOL2. The total compressive stress stored in the second region RG2 may also be represented by an area under the abovementioned function (e.g., an integral of the function) in the depth direction away from the second surface S2.

The functions of the first region RG1 and the second region RG2 may be changed depending on a kind of the glass substrate GL, a kind of the ion-exchanged ion, a condition in the ion exchange, etc. However, the functions of the first region RG1 and the second region RG2 commonly decrease in the direction toward the third region RG3 from the first surface S1, and in the direction toward the third region RG3 from the second surface S2, respectively. In the present embodiment, the two functions are shown in the form of straight lines for convenience of illustration.

When assuming that the external cation is referred to as a first ion, and assuming that the cation in the glass substrate GL is referred to as a second ion, the first ion may be K⁺, and the second ion may be Na⁺ or Li⁺.

The first compressive stress CS1 and the second compressive stress CS2 are balanced by a central tension CT stored in the third region RG3. The central tension CT is a tensile stress.

In the present embodiment, the first depth DOL1 is smaller than the second depth DOL2. Also, the first compressive stress CS1 on the first surface S1 of the glass substrate GL is smaller than the second compressive stress CS2 on the second surface S2 of the glass substrate GL. As a result, the compressive stresses on the surfaces of the glass substrate GL are asymmetric.

In the present embodiment, the glass substrate GL may have flexibility. Accordingly, the glass substrate GL can be curved, folded, or rolled. In the present embodiment, the glass substrate GL may be curved, folded, bent, or rolled in the third direction D3. That is, a portion of the first surface S1 may be folded in the direction where a portion of the first surface S1 faces another portion of the first surface S1. Alternatively, in a rolled mode, the glass substrate GL may be rolled such that a portion of the second surface S2 faces the first surface S1. When the glass substrate GL is folded or rolled, a compressive stress is applied to the first surface corresponding to an inner circumferential surface of the glass substrate GL, and a tensile strength is applied to the second surface S2 corresponding to an outer circumferential surface of the glass substrate GL.

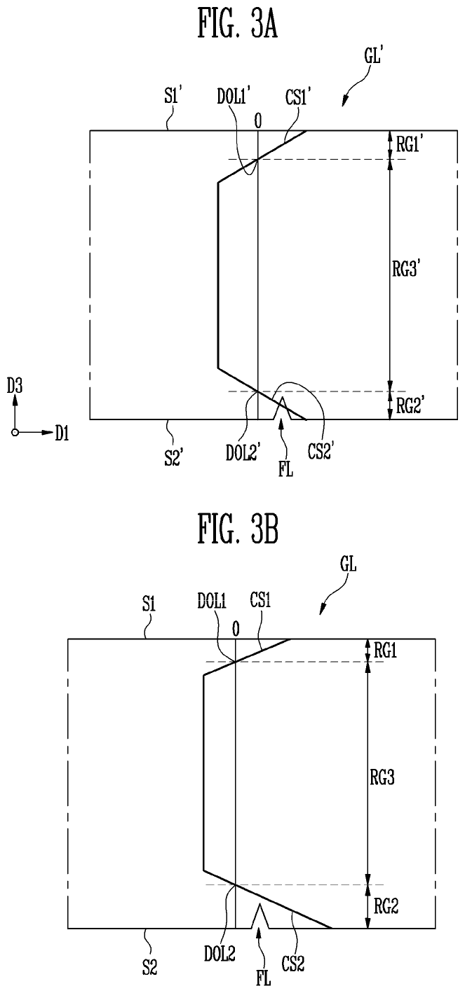

Generally, when a flaw exists in the surface at which the tensile stress is applied, the glass substrate GL may break. However, the glass substrate GL according to the present embodiment is prevented or substantially prevented from breaking due to a flaw (e.g., a discontinuity, scratch, chip, etc.) when the glass substrate GL is curved or rolled in a manner that the tensile stress is applied to the second surface S2. This will be described with reference to FIGS. 3A and 3B.

FIG. 3A is a sectional view illustrating an existing glass substrate GL′ together with a graph illustrating stresses with respect to distances from a surface of the glass substrate GL′. FIG. 3B is a sectional view illustrating the glass substrate GL according to the present embodiment together with a graph illustrating stresses with respect to distances from a surface of the glass substrate GL. To distinguish the existing glass substrate GL′ of FIG. 3A from the glass substrate GL according to the present embodiment, the name of each component corresponding to that of the present invention is used as it is, although apostrophes are added to the reference numerals/reference characters of the existing glass substrate GL′.

Referring to FIG. 3A, the existing glass substrate GL′ also has a first surface S1′ and a second surface S2′, opposite to each other. The glass substrate GL′ includes a first region RG1′ extending a first depth DOL1′ into the glass substrate GL′ from the first surface S1′, a second region RG2′ extending a second depth DOL2′ into the glass substrate GL′ from the second surface S2′, and a third region RG3′ located between the first region RG1′ and the second region RG2′. The first depth DOL1′ and the second depth DOL2′ are equal to or substantially equal to each other. Accordingly, a first compressive stress CS1′ and a second compressive stress CS2′, which are applied to the first region RG1′ and the second region RG2′, respectively, are also equal or substantially equal to each other, and are symmetric to each other.

When a flaw FL (e.g., a discontinuity, scratch, chip, etc.) is produced at a certain position of the second surface S2′ of the existing glass substrate GL′, when the flaw FL does not exist at a region defined by a reference line where the compressive stress is 0, as shown by a compressive stress graph shown in FIG. 3A, the glass substrate GL′ may be broken.

Referring to FIG. 3B, in the glass substrate GL according to the present embodiment, the first region RG1 and the second region RG2 are asymmetric to each other. The first depth DOL1 of the first region RG1 is smaller than the second depth DOL2 of the second region RG2. That is, the first depth DOL1 of the glass substrate GL according to the present embodiment is smaller than the first depth DOL1′ of the existing glass substrate GL′. Accordingly, the first compressive stress CS1 of the glass substrate GL is smaller than the first compressive stress CS1′ of the existing glass substrate GL′. Additionally, the second depth DOL2 of the glass substrate GL according to the present embodiment is larger than the second depth DOL2′ of the existing glass substrate GL′. Accordingly, the second compressive stress CS2 of the glass substrate GL is larger than the second compressive stress CS2′ of the existing glass substrate GL′.

When a flaw FL is produced at a certain position of the second surface S2 of the glass substrate GL according to the present embodiment, as shown in FIG. 3B, the flaw FL exists at or near the region defined by the reference line where the compressive stress is 0, as shown by the compressive stress graph. Accordingly, the glass substrate GL might not be broken do to stress. In other words, although a tensile stress is applied when the flaw FL exists in the second surface S2, which corresponds to the outer circumferential surface of the glass substrate GL, the second compressive stress CS2 can sufficiently compensate for the applied tensile stress. Accordingly, the glass substrate GL is prevented or substantially prevented from being damaged due to the flaw FL.

As described above, the damage of the glass substrate according to the present embodiment is reduced or minimized, even when a flaw exists in the surface to which a tensile stress is applied, when the glass substrate is folded or rolled. Particularly, when the glass substrate GL according to the present embodiment is an ultra-thin substrate, e.g., when the glass substrate GL has a thickness of less than 100 micrometers, the occurrence or growth of a flaw, which may be caused by the tensile stress when the glass substrate is folded or rolled, can be reduced. Accordingly, the possibility that the glass substrate will be broken can be significantly reduced.

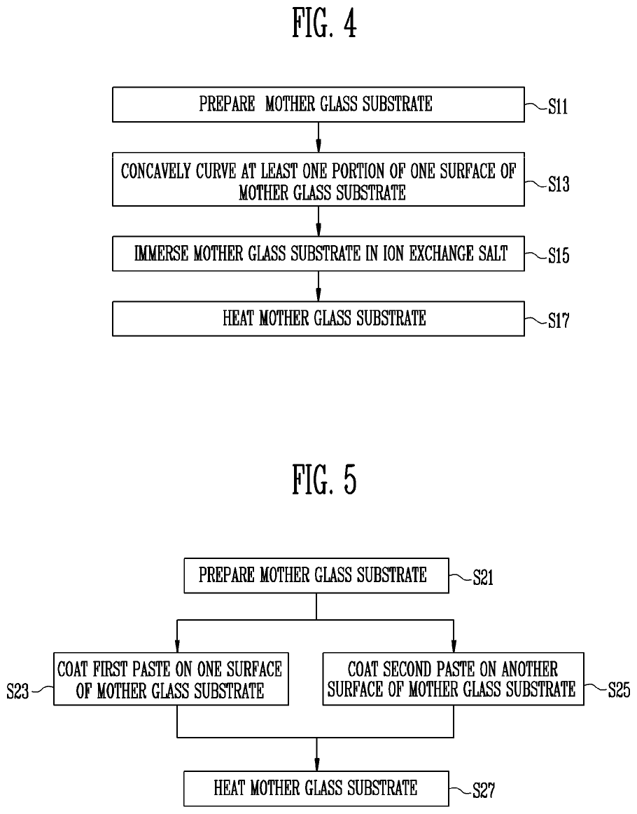

FIG. 4 is a flowchart illustrating a method of fabricating the glass substrate according to the present embodiment.

Referring to FIG. 4, the glass substrate according to the present embodiment may be fabricated by preparing a mother glass substrate (S11), concavely curving at least one portion of the mother glass substrate (S13), immersing the mother glass substrate in an ion exchange salt solution (S15), and heating the mother glass substrate (S17).

Hereinafter, an ion included in the ion exchange salt solution to be exchanged with an ion included in the mother glass substrate, and an ion included in the mother glass substrate, will be described as a first ion and a second ion, respectively.

First, there is prepared a mother glass substrate to be chemically reinforced by an ion exchange. The mother glass substrate may include alkaline aluminosilicate and/or alkaline aluminoborosilicate including an alkaline metal ion.

Next, the mother glass substrate is concavely curved. In this case, the mother glass substrate is curved corresponding to a direction in which the glass substrate is to be curved, folded, or rolled as a final product. For example, when the final glass substrate is folded or rolled such that a first surface of the final glass substrate becomes the inner circumferential surface, the mother glass substrate is also curved such that a first surface and a second surface of the mother glass substrate respectively become the inner circumferential surface and the outer circumferential surface.

Subsequently, the mother glass substrate is immersed in an ion exchange salt solution while the mother glass substrate is curved. A first ion, which is to be exchanged with a second ion in the mother glass substrate, is included in the ion exchange salt solution. The first ion is provided to the first and second surfaces of the mother glass substrate through the immersion. In the present embodiment, the first ion may be K⁺, and the second ion may be Na⁺ or Li⁺. The first and second ions may be provided in the forms of KNO₃ and NaNO₃, respectively.

Next, the immersed mother glass substrate is heated at a first temperature for a set time (e.g., a predetermined time), and the first ion, which is provided to the first and second surfaces through the heating, is diffused in the mother glass substrate through the first and second surfaces, and is exchanged with the second ion in the mother glass substrate, thereby fabricating an ion-exchanged glass substrate. Accordingly, the second ion, which originally exists in the mother glass substrate, continues to exist in the third region in the same form, and the second ion, which existed in the first and second regions, is exchanged with the first ion.

The first temperature, and the heating time for maintaining the first temperature, may be suitably set depending on a temperature at which the ions are exchanged with each other. In the present embodiment, the first temperature may be about 370° C. to about 410° C., and the heating time may be about one hour to about six hours.

In the present embodiment, an additional process may be performed on the glass substrate, and the glass substrate may be cleansed at least once or more.

As described above, the mother glass substrate is immersed in the ion exchange salt solution while the mother glass substrate is curved. As a result, the regions where the first and second surfaces of the mother glass substrate contact the ion exchange salt solution are different from each other, and the ion exchange degree of the final glass substrate is changed. As can be seen in the present embodiment, the glass substrate fabricated through the above-described processes has different depths and different compressive stresses in the first and second regions.

FIG. 5 is a flowchart illustrating another method of fabricating the glass substrate according to the present embodiment.

Hereinafter, in this description, further embodiments of the present invention will be described by highlighting differences from the above-described embodiment for convenience of illustration, and undescribed/unrepeated portions follow the above-described embodiment or contents.

Referring to FIG. 5, the glass substrate according to the present embodiment may be fabricated by preparing a mother glass substrate (S21), coating a first paste on one surface of the mother glass substrate (S23), coating a second paste on another surface of the mother glass substrate (S25), and heating the mother glass substrate (S27).

First, there is prepared a mother glass substrate to be chemically reinforced by an ion exchange. Next, different pastes are respectively coated on one of the two surfaces of the mother glass substrate. In the present embodiment, a first paste is coated on a first surface of the mother glass substrate, and a second paste, which is different from the first paste, is coated on a second surface of the mother glass substrate. One of the first and second pastes includes only a first ion, and the other of the first and second pastes includes the first ion and a second ion.

The first and second pastes to be coated on the mother glass substrate are selected by considering a direction in which the glass substrate is to be curved, folded, or rolled as a final product. When the final glass substrate is curved, folded, or rolled such that a first surface of the final glass substrate becomes the inner circumferential surface, both of the first and second ions are included in the first paste coated on the first surface of the mother glass substrate, and only the first ion is included in the second paste that is coated on the second surface of the mother glass substrate. Like the above-described embodiment, in the present embodiment, the first ion may be K⁺, and the second ion may be Na⁺ or Li⁺. In this case, the first paste may include NaNO₃, KNO₃ and ceramic powder, and the second paste may include KNO₃ and ceramic powder.

Next, the mother glass substrate having the first and second pastes coated thereon is heated at a first temperature for a set time (e.g., a predetermined time), and, due to the heating, the first and second ions are diffused in the mother glass substrate through respective ones of the first and second surfaces, and are simultaneously exchanged with each other, thereby fabricating an ion-exchanged glass substrate. The first temperature and the heating time for maintaining the first temperature may be suitably set depending on a temperature at which the ions are exchanged with each other. In the present embodiment, the first temperature may be about 370° C. to about 410° C., and the heating time may be about one hour to about six hours.

Additionally, a process of preheating the mother glass substrate before the mother glass substrate is heated may be further added. The preheating may be performed at about 300° C. to about 350° C., e.g., about 330° C., for about 70 minutes to about 110 minutes, e.g., about 90 minutes.

In the present embodiment, an additional process may be performed on the glass substrate, and the glass substrate may be cleansed at least once or more. For example, there may be provided a process of slowly cooling the mother glass substrate after the heating of the mother glass substrate is ended. The slow cooling may be performed at about 120° C. to about 170° C., e.g., about 150° C., for about 20 minutes to about 40 minutes, e.g., about 30 minutes. Also, the glass substrate may be cleansed twice. For example, the glass substrate may be primarily cleansed at about 80° C. for about 30 minutes, and secondarily cleansed at about 50° C. for about 30 minutes.

As described above, the ions are exchanged with each other in a state in which the concentration of the first ion is suitably set depending on a surface of the mother glass substrate. As a result, the frequencies where the first and second surfaces of the mother glass substrate are exposed to the first ion are different from each other, and the ion exchange degree of the final glass substrate is changed. That is, the first paste includes not only the first ion to be replaced, but also includes the second ion originally existing in the mother glass substrate, and therefore, the frequency of the first ion exchanged on the first surface is lower than that of the second ion exchanged on the first surface. As can be seen in the present embodiment, the glass substrate fabricated through the above-described processes has different depths and different compressive stresses in the first and second regions.

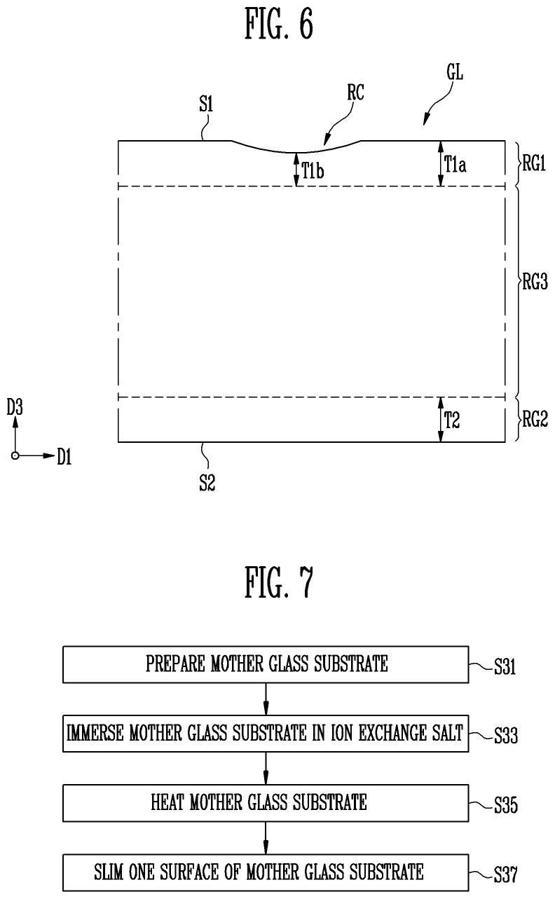

FIG. 6 is a sectional view illustrating a glass substrate according to another embodiment of the present invention.

Referring to FIG. 6, the glass substrate GL according to the present embodiment has a first surface S1 and a second surface S2, which are opposite to each other. According to the present embodiment, the first surface S1 and the second surface S2 may be parallel to each other, or may be not parallel to each other. For example, it is illustrated in FIG. 6 that the first surface S1 and the second surface S2 are not parallel to each other in a partial region, but are parallel to each other in an other region(s). Specifically, the first surface S1 may have a recess portion RC concavely recessed in the direction of the second surface S2 in the aforementioned partial region.

The glass substrate GL includes a first region RG1 extending inward to have first depths T1a and T1b from the first surface S1, a second region RG2 extending inward to have a second thickness T2 from the second surface S2, and a third region RG3 located between the first region RG1 and the second region RG2. The first thicknesses T1a and T1b in the first region RG1 have different values in a region in which the recess portion RC is formed, and in a region(s) in which the recess portion RC is not formed. The first depth T1a in the area in which the recess portion RC is not formed is greater than the first depth T1b in the area in which the recess portion RC is formed. In the present embodiment, the first depth T1b in the area in which the recess portion RC is formed may be equal to or greater than about 75% and less than about 100% of the first depth T1a in the area in which the recess portion RC is not formed. Accordingly, the region in which the recess portion RC is formed in the first region RG1 has a compressive stress that is smaller than that of the second region RG2. The area in which the recess portion RC is not formed in the first region RG1 has a compressive stress substantially equal to that of the second region RG2.

In the present embodiment, it is illustrated that the recess portion RC has a streamlined section, but the present invention is not limited thereto. The recess portion RC is not particularly limited, as long as the recess portion RC has a shape that is capable of reducing the first compressive stress, and, as such, the recess portion RC may be provided in various suitable shapes.

When viewed on a plane, the recess portion RC may be formed to various suitable sizes at various suitable positions on the glass substrate. For example, the recess portion RC may be provided in a region corresponding to a direction in which the glass substrate GL is to be folded or rolled. That is, when the glass substrate GL is folded or rolled such that the first surface S1 of the glass substrate GL becomes the inner circumferential surface, the recess portion RC may be provided on the first surface S1. Alternatively, the recess portion RC may be formed corresponding to almost all of the surface of the glass substrate GL (i.e., substantially all of the surface of the glass substrate GL, or a large portion of the surface of the glass substrate GL). In this case, the entire first region RG1 may have a smaller/more shallow depth than that of the second region RG2.

When the recess portion RC is provided to substantially the entire region or a partial region on the glass substrate GL, the thickness of the glass substrate GL in the region to which the recess portion RC is provided decreases, and hence the tensile stress generated in the glass substrate GL decreases. As a result, the glass substrate GL is more easily curved or rolled. Like the above-described embodiment, the glass substrate GL having the structure described above is prevented or substantially prevented from being broken due to a flaw when the glass substrate GL is curved or rolled in a manner that a tensile stress is applied to the second surface S2.

FIG. 7 is a flowchart illustrating a method of fabricating the glass substrate shown in FIG. 6.

Referring to FIG. 7, the glass substrate according to the present embodiment is fabricated by preparing a mother glass substrate (S31), immersing the mother glass substrate in an ion exchange salt solution (S33), heating the mother glass substrate (S35), and slimming one surface of the mother glass substrate (S37).

First, there is prepared a mother glass substrate to be chemically reinforced by an ion exchange. Next, the mother glass substrate is immersed in an ion exchange salt solution. A first ion that is to be exchanged with a second ion in the mother glass substrate is included in the ion exchange salt solution. The first ion is provided to first and second surfaces of the mother glass substrate through the immersion. In the present embodiment, the first ion may be K⁺, and the second ion may be Na⁺ or Li⁺.

Next, the immersed mother glass substrate is heated at a first temperature for a set time (e.g., a predetermined time), and the first ion provided to the first and second surfaces through the heating is diffused in the mother glass substrate through the first and second surfaces, and the first ion is exchanged with the second ion in the mother glass substrate, thereby fabricating an ion-exchanged glass substrate. The first temperature and the heating time for maintaining the first temperature may be suitably set depending on a temperature at which the first and second ions are exchanged with each other. In the present embodiment, the first temperature may be about 370° C. to about 410° C., and the heating time may be about one hour to about six hours.

The mother glass substrate is slimmed such that a recess portion is formed in at least one portion of any one of the first and second surfaces. For example, as shown in FIG. 6, the mother glass substrate may be slimmed such that a recess portion is formed in the first surface. The mother glass substrate may be slimmed using an etchant. However, the present invention is not limited thereto, and any method capable of reducing the thickness of the mother glass substrate is sufficient. For example, a sponge containing the etchant may be put in contact with a surface of the mother glass substrate, or the etchant may be repeatedly sprayed onto a region (e.g., a predetermined region) of the mother glass substrate. When the mother glass substrate is immersed in the etchant, the immersed portion of the mother glass substrate may be controlled such that a partial region is repeatedly immersed in the etchant.

In the present embodiment, the slimming of the mother glass substrate is performed after the ion exchange, but the present invention is not limited thereto. For example, the slimming of the mother glass substrate may be performed before the mother glass substrate is immersed in the ion exchange salt solution.

In the present embodiment, an additional process may be performed on the glass substrate, and the glass substrate may be cleansed at least once or more.

FIG. 8 is a graph illustrating stresses with respect to distances from a surface of a glass substrate corresponding to FIG. 1 according to still another embodiment of the present invention.

Referring to FIGS. 1 and 8, the glass substrate GL includes a first region RG1 extending to a first depth DOL1 from a first surface S1, a second region RG2 extending to a second depth DOL2 from a second surface S2, and a third region RG3 located between the first region RG1 and the second region RG2.

In the first region RG1, the first depth DOL1 is a depth at which a cation in the glass substrate GL is exchanged with an external cation. A first compressive stress CS1 is applied to the glass substrate GL by the ion exchange. The first compressive stress CS1 increases and then decreases, based on a function (e.g., a predetermined function), from the first surface S1 to the first depth DOL1. The first compressive stress CS1 becomes 0 in the first depth DOL1. Also, the first compressive stress CS1 has a maximum value at a location between the first surface S1 and the first depth DOL1. The total compressive stress stored in the first region RG1 may be represented by an area under the aforementioned function (e.g., an integral of the function) in the depth direction of a layer from the first surface S1.

In the second region RG2, the second depth DOL2 is a depth where a cation in the glass substrate GL is exchanged with an external cation. A second compressive stress CS2 is applied to the glass substrate GL by the ion exchange. The second compressive stress CS2 increases and then decreases, based on a function (e.g., a predetermined function), from the second surface S2 to the second depth DOL2. The second compressive stress CS2 becomes 0 within the second depth DOL2. Also, the second compressive stress CS2 has a maximum value at a location between the second surface S2 and the second depth DOL2. The total compressive stress stored in the second region RG2 may also be represented by an area under the aforementioned function (e.g., an integral of the function) in the depth direction of a layer from the second surface S2.

In the present embodiment, the first depth DOL1 is smaller than the second depth DOL2. The maximum value of the first compressive stress CS1 on the first surface S1 of the glass substrate GL is smaller than the maximum value of the second compressive stress CS2 on the second surface S2 of the glass substrate GL. As a result, the compressive stresses on the surfaces of the glass substrate GL are asymmetric to each other.

The first compressive stress CS1 and the second compressive stress CS2 are balanced by a central tension CT stored in the third region RG3.

In the glass substrate having the structure described above, the central tension CT corresponding to the first and second compressive stresses CS1 and CS2 has a smaller value than the central tension CT in the embodiment shown in FIG. 2. This is because the first compressive stress CS1 of the glass substrate GL of the present embodiment has a smaller value than the first compressive stress CS1 of the embodiment shown in FIG. 2, and the second compressive stress CS2 of the glass substrate GL of the present embodiment has a smaller value than the second compressive stress CS2 of the embodiment shown in FIG. 2. As such, the central tension CT corresponding to the first and second compressive stresses CS1 and CS2 is also smaller in the present embodiment.

The glass substrate generally has a safety limit (i.e., a brittle fracture limit) where the glass substrate is maintained without any damage of the glass substrate, even though a compressive stress is stored in the glass substrate. When the glass substrate has a compressive stress that exceeds the safety limit, the glass substrate may break. However, in the present embodiment, the first and second compressive stresses CS1 and CS2 decrease even though the first and second depths DOL1 and DOL2 are maintained. Thus, the central tension CT corresponding to the first and second compressive stresses CS1 and CS2 also decreases. According, the glass substrate having the structure described above is prevented or substantially prevented from being damaged due to brittle fracture.

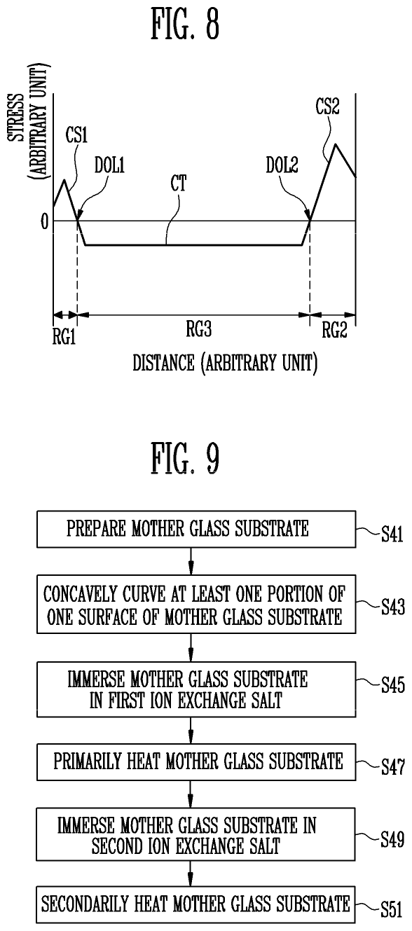

FIG. 9 is a flowchart illustrating a method of fabricating a glass substrate having the characteristic shown in the graph of FIG. 8.

Referring to FIG. 9, the glass substrate according to the present embodiment may be fabricated by preparing a mother glass substrate (S41), concavely curving at least one portion of one surface of the mother glass substrate (S43), immersing the mother glass substrate in a first ion exchange salt solution (S45), primarily heating the mother glass substrate (S47), immersing the mother glass substrate in a second ion exchange salt solution (S49), and secondarily heating the mother glass substrate (S51). The method of FIG. 9 will be described in detail as follows.

First, there is prepared a mother glass substrate to be chemically reinforced by an ion exchange. Next, the mother glass substrate is concavely curved. In this case, the mother glass substrate is curved toward a direction in which the glass substrate is to be folded, curved, bent, or rolled as a final resultant product. For example, when the finalized glass substrate is folded or rolled such that a first surface of the final glass substrate becomes the inner circumferential surface, the mother glass substrate is also curved such that a first surface and a second surface of the mother glass substrate respectively become the inner circumferential surface and the outer circumferential surface.

Subsequently, the mother glass substrate is immersed in a first ion exchange salt solution when the mother glass substrate is curved. A first ion to be exchanged with a second ion, which is in the mother glass substrate, is included in the first ion exchange salt solution. The first ion is provided to the first and second surfaces of the mother glass substrate through the immersion. In the present embodiment, the first ion may be K⁺, and the second ion may be Na⁺ or Li⁺.

Next, the immersed mother glass substrate is primarily heated at a first temperature for a set time (e.g., a predetermined time), and the first ion provided to the first and second surfaces through the primary heating is diffused in the mother glass substrate through the first and second surfaces, and the first ion is exchanged with the second ion in the mother glass substrate. The first temperature, and the primary heating time for maintaining the first temperature, may be suitably set depending on the kinds of the ions, a degree to which the ions are exchanged with each other, and the like. In the present embodiment, the first temperature may be about 370° C. to about 410° C., and the primary heating time may be about one hour to about six hours.

Next, the mother glass substrate is immersed in a second ion exchange salt solution while the mother glass substrate is curved. A second ion, which is the same as the second ion in the mother glass substrate, is included in the second ion exchange salt solution. The second ion is provided to the first and second surfaces of the mother glass substrate through the immersion.

Next, the immersed mother glass substrate is secondarily heated at a second temperature for a set time (e.g., a predetermined time), and the second ion provided to the first and second surfaces through the secondary heating is diffused in the mother glass substrate through the first and second surfaces. The first ion is exchanged with the second ion in the mother glass substrate, thereby fabricating an ion-exchanged glass substrate. The second temperature, and the secondary heating time for maintaining the second temperature, may be suitably set depending on the kinds of the ions, a degree where the ions are exchanged with each other, and the like. The secondary heating may be performed at a lower temperature and for a shorter time than the primary heating. In the present embodiment, the second temperature may be about 370° C. to about 390° C., and the secondary heating time may be about 10 minutes to about 20 minutes.

In the present embodiment, an additional process may be performed on the glass substrate, and the glass substrate may be cleansed at least once or more.

The glass substrate having the characteristics shown in the graph of FIG. 8 can be fabricated by the above-described processes, although the present invention is not limited thereto. It will be obvious to those skilled in the art that the glass substrate may be fabricated by modifying the method using the first and second pastes, which is disclosed in FIG. 4. Therefore, its description will be omitted.

The glass substrate according to the present embodiment may be employed in various suitable devices. For example, the glass substrate may be employed in a display device. The glass substrate may be used as a base substrate on which elements (or components) are mounted in the display device. Also, the glass substrate may be used as an opposite substrate facing the base substrate, or may be used as a window panel disposed on a display substrate, or may be used as a substrate of a touch screen panel provided on the display substrate.

FIG. 10 is a perspective view illustrating a display device DP employing a glass substrate according to an embodiment of the present invention.

Referring to FIG. 10, the display device DP may be provided in various suitable shapes. For example, the display device DP may be a rectangular plate shape having two pairs of parallel sides. When the display device DP is rectangular, any one pair of sides out of the two pairs of sides may be longer than the other pair of sides. In the present embodiment, it is illustrated that, for convenience of illustration, that the display device DP has a rectangular shape having a pair of long sides and a pair of short sides. In addition, the direction of extension of the long sides is designated as a first direction D1, the direction of extension of the short sides is designated as a second direction D2, and the direction perpendicular to the directions of extension of the long side and the short side (i.e., first and second directions D1 and D2) is designated as a third direction D3.

The display device DP according to the present embodiment includes a glass substrate GL and a device layer DV provided on the glass substrate GL to display images.

The glass substrate GL is plated shaped and has a first surface S1, and a second surface S2 opposite to the first surface S1, and the device layer DV may be formed on any one of the first and second surfaces S1 and S2.

The glass substrate GL may be a glass that is chemically reinforced by the ion exchange process disclosed in the above-described embodiments.

According to the present embodiment, the device layer DV is provided on the first surface S1 of the glass substrate GL. The device layer DV may include pixels used in the display device DP. However, the present invention is not limited thereto, and the device layer DV may be provided as various suitable types, such as a memory device according to devices to be formed.

The pixel may include lines, a thin film transistor connected to the lines, an electrode switched by the thin film transistor, and an image display layer controlled by the electrode.

The lines may include a plurality of gate lines and a plurality of data lines that cross the gate lines.

The thin film transistor may be provided in plurality such that passive matrix driving or active matrix driving is possible. When the thin film transistor is provided as an active matrix thin film transistor, the thin film transistor is provided in plurality, and each of the plurality of thin film transistors is connected to a corresponding gate line among the gate lines, and is connected to a corresponding data line among the data lines.

The electrode may be provided in plurality, and the plurality of electrodes may be connected to respective ones of the thin film transistors.

Each thin film transistor includes a gate electrode, an active layer, a source electrode, and a drain electrode. The gate electrode may branch from a corresponding gate line among the gate lines. The active layer is formed to be insulated from the gate electrode, and the source and drain electrodes are spaced apart from each other on the active layer such that the active layer is exposed. The source electrode may branch from a corresponding data line among the data lines.

The image display layer DV may include a liquid crystal layer, an electrophoretic layer, an electro-wetting layer, an organic light emitting layer, and the like according to the manner in which the images are to be displayed. The image display layer DV is driven corresponding to a voltage applied to the electrode(s).

The device layer DV may further include an opposite glass substrate with the image display layer interposed therebetween, the opposite glass substrate facing the glass substrate GL. In this case, the opposite glass substrate may be substantially the same shape as the glass substrate GL. Therefore, its description will be omitted.

The display device DP may be flat, as shown in FIG. 10. However, the display device DP may be differently shaped by modifying at least one portion of the display device DP.

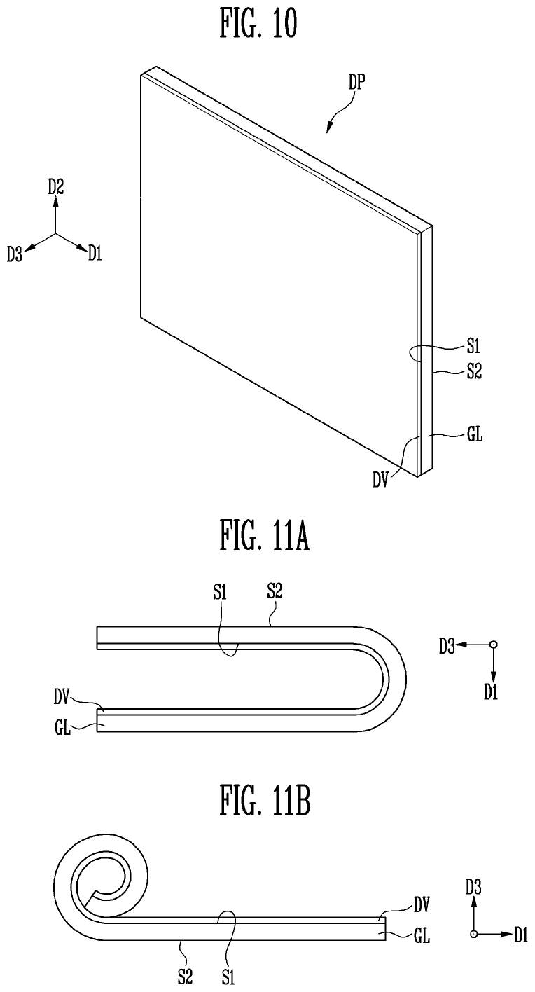

FIG. 11A is a sectional view illustrating when the display device of FIG. 10 is folded, and FIG. 11B is a sectional view illustrating when the display device of FIG. 10 is rolled.

Referring to FIGS. 11A and 11B, together with FIG. 10, at least one portion of the display device DP according to the present embodiment may have flexibility. Alternately, the entire display device DP may have flexibility. Since the display device DP has flexibility in the region having flexibility, the display device DP may be folded as shown in FIG. 11A, or may be rolled as shown in FIG. 11B.

Hereinafter, the display device that can be folded as shown in FIG. 11A is referred to as a foldable display device, and the display device that can be rolled as shown in FIG. 11B is referred to as a rollable display device. In the foldable display device, the state in which the display is flat, as shown in FIG. 10, is referred to as a flat mode, and the state in which the display device is folded, as shown in FIG. 11A, is referred to as a folded mode. In the rollable display device, the state in which the display device is flat, as shown in FIG. 10, is referred to as a flat mode, and the state in which the display device is rolled, as shown in FIG. 11B, is referred to as a rolled mode.

Referring back to FIG. 11A, the display device may be folded in a direction such that a portion of the first surface S1 faces the other portion of the first surface S1. Since the device layer DV is formed on the first surface S1, the display device may be folded in a direction in which images are displayed in the folded mode. In other words, the display device may be folded such that a portion of the device layer DV faces another portion of the device layer DV in the folded mode. The folding line along which the display device is folded may be parallel to the second direction D2 while passing through, or near, the center of the display device. However, the position of the folding line is not limited thereto. The folding line may be in a direction parallel to the first direction D1, may be in the first direction D1, or may be a direction that is diagonal to the first or second direction D1 or D2. It will be apparent that the folding line may not pass through the center of the display device.

Next, referring to FIG. 11B, the display device may be rolled such that a portion of the second surface S2 faces the first surface S1 in the rolled mode. Since the device layer DV is formed on the first surface S1, the display device may be rolled in a direction in which images are displayed in the rolled mode. In other words, the display device may be rolled such that the second surface S2 of the glass substrate GL faces or contacts the device layer DV in the rolled mode. The direction in which the display device is rolled may be the first or second direction D1 or D2. However, the rolled direction is not limited thereto, and the display device may be rolled in a direction diagonal to the first or second direction D1 or D2. In the display device, the rolled region may be a portion of the display device, and the entire area may be rolled.

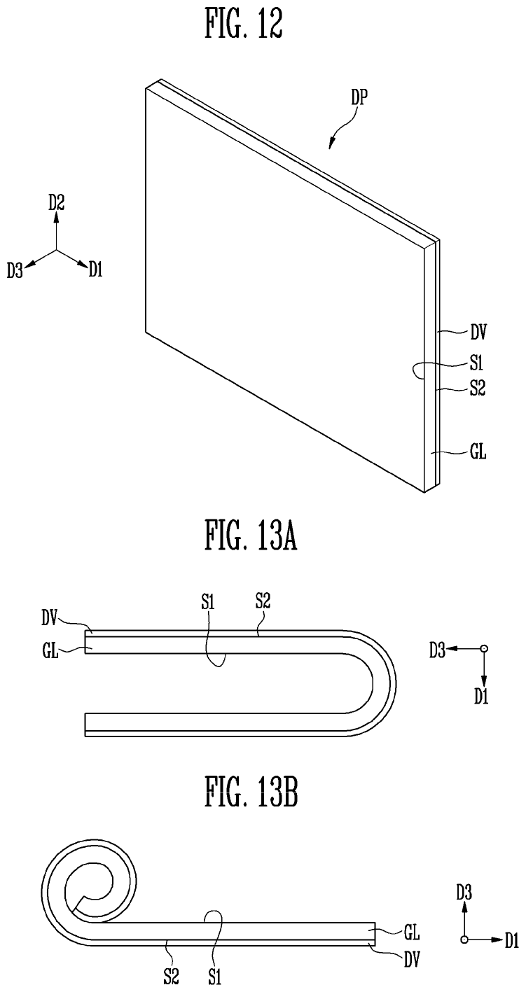

FIG. 12 is a perspective view illustrating another example of the display device employing the glass substrate according to an embodiment, FIG. 13A is a sectional view illustrating when the display device of FIG. 12 is folded, and FIG. 13B is a sectional view illustrating when the display device of FIG. 12 is rolled.

Referring to FIG. 12, the display device DP according to the present embodiment includes a glass substrate GL, and a device layer DV on the glass substrate to display images.

The glass substrate GL is plate shaped, and has a first surface S1 and a second surface S2 that is opposite to the first surface S1. The device layer DV is provided on the second surface S2 of the glass substrate GL.

Referring to FIG. 13A, like the display device shown in FIG. 11A, the display device may be folded in a direction in which a portion of the first surface S1 faces another portion of the first surface S1. However, in the display device according to the present embodiment, the device layer DV is formed on the second surface S2, and therefore, the display device may be folded in a direction opposite to the direction in which images are displayed in the folded mode. In other words, the display device may be folded such that a portion of the surface, which is opposite to the surface on which the device layer DV is formed, faces another portion of the surface in the folded mode.

Referring to FIG. 13B, like the display device shown in FIG. 11B, the display device may be rolled such that a portion of the second surface S2 faces the first surface S1 in the rolled mode. However, in the display device according to the present embodiment, the device layer DV is formed on the second surface S2, and therefore, the display device may be rolled in a direction opposite to the direction in which images are displayed in the rolled mode. In other words, the display device may be rolled such that a portion of the device layer DV faces or contacts the first surface S1 in the rolled mode.

In the present embodiment, the entire display device may have flexibility, but the present invention is not limited thereto. When the folded region or the rolled region corresponds to only a portion of the display device, flexibility might be provided to only the folded region or the rolled region.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, components, and/or elements described in connection with a particular embodiment may be used singly or in combination with features, characteristics, components, and/or elements described in connection with other embodiments unless otherwise specifically indicated. Accordingly, it will be understood by those of skill in the art that various suitable changes in form and details may be made without departing from the spirit and scope of the present invention as set forth in the following claims and their equivalents.

What is claimed is:

1. A method of fabricating a glass substrate, the method comprising:
preparing a mother glass substrate having a first surface and a second surface opposite the first surface;
concavely curving at least one portion of the first surface of the mother glass substrate;
immersing the mother glass substrate in a first ion exchange salt solution comprising a first ion while the mother glass substrate is curved; and
primarily heating the mother glass substrate.

2. The method of claim 1, further comprising immersing the mother glass substrate in a second ion exchange salt solution comprising a second ion different from the first ion.

3. The method of claim 2, further comprising secondarily heating the mother glass substrate after the mother glass substrate is immersed in the second ion exchange salt solution.

4. The method of claim 3, wherein the secondary heating is performed at a lower temperature and for a shorter time than the primary heating.

5. The method of claim 2, wherein the first ion is a K⁺ ion, and
wherein the second ion is a Na⁺ ion.

6. A method of fabricating a glass substrate, the method comprising:
preparing a mother glass substrate having a first surface and a second surface opposite the first surface;
coating a first dry paste comprising a first ion on the first surface;
coating a second dry paste comprising the first ion and a second ion on the second surface; and
heating the mother glass substrate on which the first and second dry pastes are coated.

7. The method of claim 6, wherein the first ion is a K⁺ ion, and
wherein the second ion is a Na⁺ ion.

8. A method of fabricating a glass substrate, the method comprising:
preparing a mother glass substrate having a first surface and a second surface opposite the first surface;
immersing the mother glass substrate in an ion exchange salt solution;
heating the mother glass substrate; and
slimming the first surface of the mother glass substrate.
